(19) United States
(12) Patent Application Publication
(10) Pub. No.: US 2024/0234626 A9
(43) Pub. Date: Jul. 11, 2024

(54) METHOD FOR PRODUCING AN OPTOELECTRONIC SEMICONDUCTOR COMPONENT AND OPTOELECTRONIC SEMICONDUCTOR COMPONENT

(71) Applicant: ams-OSRAM International GmbH, Regensburg (DE)

(72) Inventors: Jens Ebbecke, Rohr in Niederbayern (DE); Kristina Schelestow, Regensburg (DE); Markus Graul, Regensburg (DE); Hans-Joachim Meyer, Regensburg (DE); Richard Floeter, Tegernheim (DE)

(21) Appl. No.: 18/546,582

(22) PCT Filed: Feb. 23, 2022
(86) PCT No.: PCT/EP2022/054498

§ 371 Date: Aug. 15, 2023

(30) Foreign Application Priority Data
Feb. 26, 2021 (DE) 10 2021 104 685.8

(51) Int. Cl. H01L 33/06; H01L 33/00; H01L 33/02

(52) U.S. Cl. CPC H01L 33/06; H01L 33/0075; H01L 33/0095; H01L 33/025

(57) ABSTRACT

In an embodiment a method for producing an optoelectronic semiconductor component includes A) providing a semiconductor body comprising, sequentially in a vertical direction, a first layer of a first conductivity type, an active layer formed as a quantum well structure provided for emission of electromagnetic radiation, and a second layer of a second conductivity type and B) irradiating the semiconductor body with a focused electromagnetic radiation such that a focus region of the electromagnetic radiation lies within the active layer and overlaps with the quantum well structure, wherein the electromagnetic radiation has an intensity which is sufficiently large in the focus region to cause point defects in the quantum well structure so that a defect region is formed and so that a generation of the point defects is limited to the focus region, and wherein a density of point defects in the first layer and the second layer is not changed in B).

### CROSS-REFERENCE TO RELATED APPLICATIONS

This patent application is a national phase filing under section 371 of PCT/EP2022/054498, filed Feb. 23, 2022, which claims the priority of German patent application 102021104685.8, filed Feb. 26, 2021, each of which is incorporated herein by reference in its entirety.

### TECHNICAL FIELD

A method for producing an optoelectronic semiconductor component and an optoelectronic semiconductor component are disclosed. The optoelectronic semiconductor component is especially configured to generate electromagnetic radiation, preferably light perceptible to the human eye.

### SUMMARY

Embodiments provide an optoelectronic semiconductor component is, for example, a luminescent diode, in particular a semiconductor laser diode, which is set up to emit coherent electromagnetic radiation.

Further embodiments provide a method for producing an optoelectronic semiconductor component having improved efficiency.

Yet other embodiments provide an optoelectronic semiconductor component which exhibits improved efficiency.

According to at least one embodiment of the method for producing an optoelectronic semiconductor component, a semiconductor body comprising, in a vertical direction, successively, a first layer of a first conductivity type, an active layer formed as a quantum well structure configured for emission of electromagnetic radiation, and a second layer of a second conductivity type is provided.

Preferably, the semiconductor body comprises several layers that are epitaxially grown on top of each other in a stacking direction. The vertical direction runs parallel to the stacking direction of the semiconductor body and in particular perpendicular to a main extension plane of the semiconductor body. Each semiconductor layer of the semiconductor body may have several layers of different composition.

For example, the active layer comprises a pn junction formed as a quantum well structure. For example, the quantum well structure comprises a single quantum well (SQW) structure or a multi-quantum well (MQW) structure for generating electromagnetic radiation during operation of the optoelectronic semiconductor component.

Preferably, the first layer and the second layer have different electrical conductivity types from each other. For example, the first layer has a p-type conductivity and the second layer has an n-type conductivity. The conductivity type of the respective semiconductor layers is preferably adjusted by means of doping.

According to at least one embodiment of the method for producing an optoelectronic semiconductor component, the semiconductor body is irradiated with focused electromagnetic radiation such that a focus region of the electromagnetic radiation lies within the active layer and overlaps with the quantum well structure, wherein the electromagnetic radiation has an intensity which is sufficiently large in the focus region to cause point defects in the quantum well structure so that a defect region is formed and the generation of the point defects is limited to the focus region.

The focus region describes an area in which the focused electromagnetic radiation has an intensity maximum along its propagation direction. The focused electromagnetic radiation is in particular a focused Gaussian beam. For example, the focused electromagnetic radiation is coherent and is generated by a laser.

A point defect is in particular a point-shaped defect in a crystal lattice. For example, a vacancy or an intrinsic interstitial atom forms a point defect. When a crystal lattice is irradiated with electromagnetic radiation of a sufficiently high intensity, such point defects form in the crystal lattice.

The defect region is in particular a region in the semiconductor body in which a density of point defects is increased compared to an original region immediately adjacent in the lateral direction. The lateral direction is in particular perpendicular to the vertical direction.

In particular, the original region is not irradiated by the electromagnetic radiation and thus does not have an increased density of point defects. For example, the defect region is formed only in a part of the active layer and a part of the active layer remains unchanged in the original region.

Advantageously, the generation of point defects is limited to the focus region, since only there is a sufficiently high intensity of electromagnetic radiation to change the crystal lattice of the semiconductor body. Thus, a locally limited increase of a density of point defects can be achieved. An increased density of point defects in the first layer and/or in the second layer can advantageously be reduced or avoided. A low density of point defects advantageously leads to a high radiation transmission in the first layer and in the second layer. Consequently, the optoelectronic semiconductor component exhibits improved efficiency.

According to at least one embodiment of the method for producing an optoelectronic semiconductor component, the method comprises the following steps:
A) providing a semiconductor body comprising, sequentially in a vertical direction, a first layer of a first conductivity type, an active layer formed as a quantum well structure provided for emission of electromagnetic radiation, and a second layer of a second conductivity type, and
B) irradiating the semiconductor body with a focused electromagnetic radiation such that a focus region of the electromagnetic radiation is within the active layer and overlaps with the quantum well structure, wherein
the electromagnetic radiation has an intensity sufficiently large in the focus region to cause point defects in the quantum well structure so that a defect region is formed and the generation of the point defects is confined to the focus region.

Advantageously, the process for fabricating an optoelectronic semiconductor component is carried out in parallel on a plurality of optoelectronic semiconductor components in a wafer composite.

A method described herein for the fabrication of an optoelectronic semiconductor component is based, inter alia, on the following considerations: In conventional processes for the generation of point defects in a semiconductor body, a high density of point defects is first generated at a surface of the semiconductor body, for example by means of irradiation by non-focused UV radiation or the deposition of dielectric layers with different thermal expansion coefficients. In a further step, the point defects diffuse from the surface into the semiconductor body, for example to induce a desired quantum well intermixing in an active layer. However, this also leaves an increased density of unwanted point defects in the regions of the semiconductor body between the surface and the active layer. An increased density of point defects outside the active layer can result in adverse effects, such as reduced radiation transmittance of the semiconductor body, and thus reduced efficiency.

The method described herein for producing an optoelectronic semiconductor component makes use, among other things, of the idea of generating point defects by means of irradiating the active layer of the semiconductor body with focused electromagnetic radiation. Thus, a density of point defects can be selectively achieved within the active layer without creating point defects in vertically adjacent regions of the active layer. A density of point defects in the rest of the semiconductor body thus remains as low as possible. Thus, a radiation transmittance of the semiconductor body and consequently also an efficiency of the optoelectronic semiconductor component can be advantageously increased.

According to at least one embodiment of the method for producing an optoelectronic semiconductor component, a density of point defects in the defect region of at least 1*10¹³ cm⁻³ and of at most 1*10¹⁹ cm⁻³ is generated in step B). By means of a density of point defects between 1*10¹³ cm⁻³ and 1*10¹⁹ cm⁻³, quantum well intermixing can be generated in the quantum well structure in a further process step, for example.

According to at least one embodiment of the method for producing an optoelectronic semiconductor component, a density of point defects in the first layer and the second layer is not changed in the step B). In particular, a density of point defects in the first layer and the second layer after the step B) is unchanged from a density of point defects before the step B). A low density of point defects in the first layer and/or the second layer enables an advantageously high radiation transmittance of the semiconductor body.

According to at least one embodiment of the method for producing an optoelectronic semiconductor component, an annealing step is performed in a further step C) such that a conversion region is generated from the defect region, wherein a band gap in the conversion region is changed with respect to a laterally adjacent original region.

For example, in the annealing step, quantum well intermixing takes place in the quantum well structure in the defect region. By means of quantum well intermixing, the conversion region can be generated in the defect region, the band gap of which is changed with respect to a laterally adjacent original region. The conversion region preferably covers part of the active layer. Advantageously, a change in the band gap in the active layer can thus only take place locally. For example, a region can be created in the active layer in which a reduced charge carrier density occurs during operation of the optoelectronic semiconductor component.

According to at least one embodiment of the optoelectronic process, the annealing step is carried out at a temperature of at least 800° C. and at most 900° C. A higher temperature leads to an increased reaction rate, resulting in sufficient quantum well intermixing in a shorter time. Too high a temperature can lead to thermal damage to the optoelectronic semiconductor component.

According to at least one embodiment of the method of fabricating an optoelectronic semiconductor component, the annealing step is performed over a time period of at least 30 seconds and at most 20 minutes. For sufficient quantum well intermixing, a sufficient time period of the annealing step is advantageous. Compared to a conventional process for quantum well intermixing with point defects, which must first diffuse from a surface of the semiconductor body into the active layer, the time duration of the annealing step can be significantly reduced, since the point defects are already present in the defect region in the active region. The shortest possible time duration is advantageous in order to keep a thermal stress on the optoelectronic semiconductor component as low as possible.

According to at least one embodiment of the method for producing an optoelectronic semiconductor component, the annealing step is carried out at a temperature between 890° C. and 910° C. over a period of 1 to 10 minutes. These process parameters advantageously result in sufficient quantum well intermixing at an advantageously low thermal stress for the optoelectronic semiconductor component.

According to at least one embodiment of the method for producing an optoelectronic semiconductor component, the irradiation of the semiconductor body with the electromagnetic radiation in step B) is performed parallel to the vertical direction. An irradiation parallel to the vertical direction allows a particularly precise delimitation of the defect region. A perpendicular incidence of the electromagnetic radiation advantageously reduces an influence on material vertically above and below the active layer.

According to at least one embodiment of the method for producing an optoelectronic semiconductor component, a diameter of the focus region is set to a diameter between 50 nm and 10 μm, preferably to a diameter between 100 nm and 200 nm. The diameter is the longest distance within the focus region that passes through a center of the focus region.

For example, the focus diameter is set by means of optical elements, in particular lenses. A minimum focus diameter is determined, among other things, by the wavelength of the electromagnetic radiation used. A small diameter of the focus region advantageously allows particularly precise control of the irradiation of the active layer of the semiconductor body. With a larger diameter of the focus region, a larger volume of the active layer can advantageously be irradiated in a shorter time.

According to at least one embodiment of the method for producing an optoelectronic semiconductor component, the electromagnetic radiation has a main wavelength corresponding to a photon energy smaller than a bandgap of the semiconductor material in the first layer and/or in the second layer. The main wavelength of an electromagnetic radiation is a wavelength at which a spectrum of the electromagnetic radiation has a global intensity maximum.

An electromagnetic radiation having a main wavelength corresponding to a photon energy smaller than a band gap of the semiconductor material in the first layer and or in the second layer can advantageously penetrate the first layer and or the second layer particularly unhindered. A generation of point defects in the first layer and or in the second layer can thus be advantageously reduced or avoided.

According to at least one embodiment of the method for producing an optoelectronic semiconductor component, the electromagnetic radiation has a main wavelength corresponding to a photon energy that is greater than a band gap of the semiconductor material in the active layer. An electromagnetic radiation having a main wavelength corresponding to a photon energy larger than a band gap of the semiconductor material in the active layer is advantageously absorbed particularly well in the active layer. Good absorption enables particularly efficient formation of point defects in the active layer.

According to at least one embodiment of the method for producing an optoelectronic semiconductor component, the electromagnetic radiation is a coherent radiation. A coherent radiation has a particularly large coherence length and consequently a narrow spectral bandwidth. In particular, a laser radiation has a high coherence length. By means of coherent radiation, a precise generation of point defects in a crystal lattice of the semiconductor body is advantageously possible.

Furthermore, an optoelectronic semiconductor component is disclosed. In particular, the optoelectronic semiconductor component is manufactured by the method for producing an optoelectronic semiconductor component described herein. That is, all features disclosed for the optoelectronic semiconductor component are also disclosed for the method, and vice versa.

According to at least one embodiment of the optoelectronic semiconductor component, the optoelectronic semiconductor component has a semiconductor body comprising, in a vertical direction: a first layer having a first conductivity, an active layer, and a second layer having a second conductivity.

According to at least one embodiment of the optoelectronic semiconductor component, the active layer is formed as a quantum well structure configured to emit electromagnetic radiation.

According to at least one embodiment of the optoelectronic semiconductor component, a conversion region is formed in the active layer, at least in regions, in which a band gap is changed with respect to an original region laterally adjacent thereto. For example, a band gap in the conversion region is larger than a band gap in the original region.

According to at least one embodiment of the optoelectronic semiconductor component, a density of point defects in the first layer and the second layer vertically below and above the conversion region is the same as a density of point defects in the first layer and the second layer vertically below and above the original region. In other words, the density of point defects in the first layer and in the second layer is constant in a direction transverse to the vertical direction, respectively. Constant here and in the following means equal within a manufacturing tolerance.

According to at least one embodiment of the optoelectronic semiconductor component, the optoelectronic semiconductor component comprises
a semiconductor body comprising in a vertical direction: a first layer of a first conductivity type, an active layer, and a second layer of a second conductivity type, wherein
the active layer is formed as a quantum well structure intended for the emission of electromagnetic radiation,
a conversion region is formed in the active layer, at least in regions, in which a band gap is changed with respect to an original region laterally adjacent thereto, and
a density of point defects in the first layer and the second layer vertically below and above the conversion region is equal to a density of point defects in the first layer and the second layer vertically below and above the original region.

According to at least one embodiment of the optoelectronic semiconductor component, the conversion region extends into the first layer from an interface of the active layer to the first layer to at most half of a thickness of the active layer.

According to at least one embodiment of the optoelectronic semiconductor component, the conversion region extends from an interface of the active layer to the second layer into the second layer up to at most half of the thickness of the active layer. The thickness of the active layer corresponds to an extension of the active layer in the vertical direction. Preferably, the conversion region is predominantly limited in its extension in the vertical direction to the active layer and extends only partially into the first layer and the second layer. In this way, undesirable interference with the first and/or the second layer can be reduced or avoided. In particular, the first and/or the second layer thus retain a high radiation transmission and absorb as little electromagnetic radiation as possible.

According to at least one embodiment, the conversion region extends into the semiconductor body in a lateral direction starting from a facet of the semiconductor body between 1 μm and 1000 μm, preferably between 10 μm and 50 μm. A facet of the semiconductor body is an outer surface of the semiconductor body extending in the vertical direction, which can be set up as a radiation exit surface. In particular, a facet has a smooth surface and acts as an at least partially transparent mirror.

The arrangement of the conversion region on the facets of the semiconductor body reduces a charge carrier density on these surfaces, thereby reducing a recombination probability. A low recombination probability reduces a generation of heat at the facets, whereby a damage of the facets can be avoided.

According to at least one embodiment of the optoelectronic semiconductor component, the semiconductor body is based on a III/V compound semiconductor material. III/V compound semiconductor materials are suitable, for example, for the production of optoelectronic semiconductor components which emit electromagnetic radiation in the infrared spectral range during operation.

A III/V compound semiconductor material comprises at least one element from the third main group, such as B, Al, Ga, In, and one element from the fifth main group, such as N, P, As. In particular, the term “III/V compound semiconductor material” includes the group of binary, ternary or quaternary compounds containing at least one element from the third main group and at least one element from the fifth main group, for example nitride and phosphide compound semiconductors. Such a binary, ternary or quaternary compound may further comprise, for example, one or more dopants as well as additional constituents.

According to at least one embodiment of the optoelectronic semiconductor component, the semiconductor body is based on one of the following compound semiconductor materials: nitride compound semiconductor material, phosphide compound semiconductor material, or arsenide compound semiconductor material.

“Based on nitride compound semiconductor material” means in the present context that the semiconductor body or at least a part thereof, particularly preferably at least the active layer and/or a growth substrate wafer, comprises or consists of a nitride compound semiconductor material, preferably AlₙGaₘIn₁₋ₙ₋ₘN, where 0≤n≤1, 0≤m≤1 and n+m≤1. In this context, this material does not necessarily have to have a mathematically exact composition according to the above formula. Rather, it may have, for example, one or more dopants as well as additional constituents. For the sake of simplicity, however, the above formula includes only the essential constituents of the crystal lattice (Al, Ga, In, N), even if these may be partially replaced and/or supplemented by small amounts of other substances.

“Phosphide compound semiconductor material based” in this context means that the semiconductor body or at least a part thereof, particularly preferably at least the active layer and/or a growth substrate wafer, preferably comprises AlₙGaₘIn₁₋ₙ₋ₘP or AsₙGaₘIn₁₋ₙ₋ₘP, where 0≤n≤1, 0≤m≤1 and n+m≤1. In this context, this material does not necessarily have to have a mathematically exact composition according to the above formula. Rather, it may have one or more dopants as well as additional constituents. For the sake of simplicity, however, the above formula contains only the essential constituents of the crystal lattice (Al or As, Ga, In, P), even if these may be partially replaced by small amounts of other substances.

“Arsenide compound semiconductor material based” in this context means that the semiconductor body or at least a part thereof, particularly preferably at least the active layer and/or a growth substrate wafer, preferably comprises AlₙGaₘIn₁₋ₙ₋ₘAs, where 0≤n≤1, 0≤m≤1 and n+m≤1. This material does not necessarily have to have a mathematically exact composition according to the above formula. Rather, it may have one or more dopants as well as additional constituents. For the sake of simplicity, the above formula includes but only the essential constituents of the crystal lattice (Al or As, Ga, In), even if these may be partially replaced by small amounts of other substances.

In particular, the semiconductor body is formed with InGaAlP or InGaAs.

An optoelectronic semiconductor component described herein is particularly suitable for use as a high-power luminescent diode, especially as a high-power laser diode, for example for use in a projection device for augmented reality applications or as a high-power laser diode in the infrared spectral range for material processing.

### BRIEF DESCRIPTION OF THE DRAWINGS

Further advantages and advantageous design examples and further embodiments of the optoelectronic semiconductor component result from the following exemplary embodiments shown in connection with the figures.

FIG. 1 shows a schematic sectional view of an optoelectronic semiconductor component according to a first embodiment in a step of a method for its production;

FIG. 2 shows a schematic sectional view of an optoelectronic semiconductor component according to the first embodiment in a further step of a method for its production;

FIG. 3 shows several photoluminescence spectra of an optoelectronic semiconductor component according to the first embodiment in different stages of a method for its production;

FIG. 4 shows a schematic top view of a wafer composite with a plurality of optoelectronic semiconductor components according to the first embodiment; and

FIG. 5 shows a schematic top view of an optoelectronic semiconductor component according to a second embodiment.

### DETAILED DESCRIPTION OF ILLUSTRATIVE EMBODIMENTS

Elements that are identical, similar or have the same effect are given the same reference signs in the figures. The figures and the proportions of the elements shown in the figures are not to be regarded as to scale. Rather, individual elements may be shown exaggeratedly large for better representability and/or for better comprehensibility.

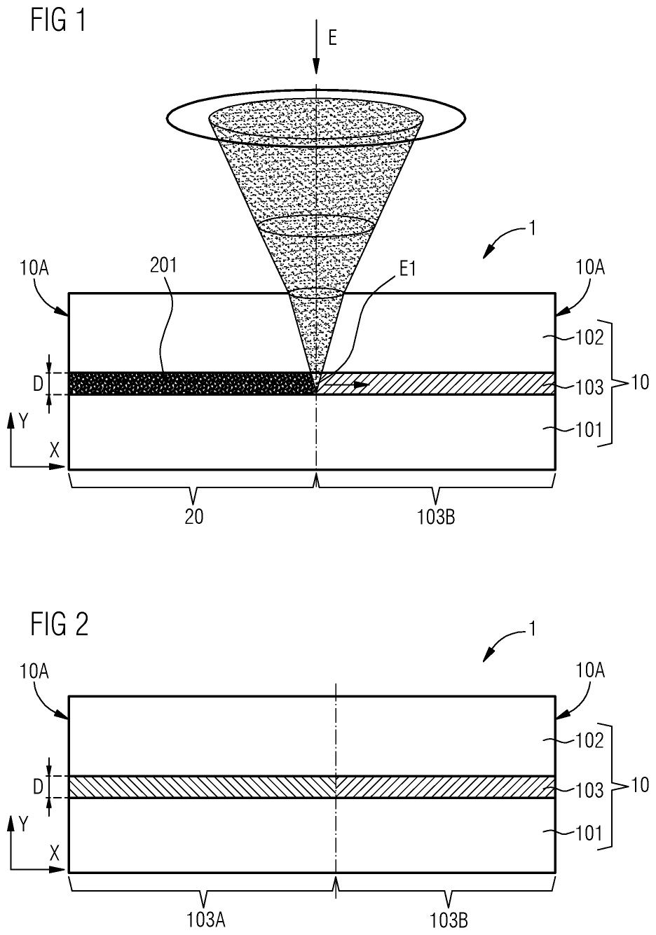

FIG. 1 shows a schematic sectional view of an optoelectronic semiconductor component 1 according to a first embodiment with a semiconductor body 10 in a step of a method for its production.

The semiconductor body 10 is formed with InGaAlP or InGaAs and comprises a first layer 101, an active layer 103, and a second layer 102 sequentially in a vertical direction Y. The vertical direction Y is parallel to a stacking direction of the semiconductor body 10 and perpendicular to a main extension plane of the semiconductor body 10.

The semiconductor body 10 includes two facets 10A extending parallel to the vertical direction Y and forming outer surfaces of the semiconductor body 10. The facets 10A limit the extent of the semiconductor body 10 in a lateral direction X. The lateral direction X is perpendicular to the vertical direction Y and thus parallel to a main extension plane of the semiconductor body 10.

The first layer 101 has a first conductivity type and the second layer 102 has a second conductivity type different from the first conductivity type. The active layer 103 comprises a pn junction and is configured to generate electromagnetic radiation. Further, the active layer 103 comprises a quantum well structure. The active layer 103 has a thickness D. The thickness D corresponds to an extension of the active layer 103 in the vertical direction Y. For example, the thickness D is 1 μm.

In the illustrated step of the method, the semiconductor body 10 is irradiated with a focused electromagnetic radiation E parallel to the vertical direction Y. The electromagnetic radiation E includes a focus region E1 located within the active layer 103 and overlapping with the quantum well structure. The electromagnetic radiation E1 has a main wavelength corresponding to a photon energy smaller than a band gap of the semiconductor material in the first layer 101 and a band gap of the semiconductor material in the second layer 102, and corresponding to a photon energy larger than a band gap of the semiconductor material in the active layer 103.

Thus, absorption of the electromagnetic radiation E preferably occurs in the active layer 103. An intensity of the electromagnetic radiation E in the focus region E1 within the active layer 103 is sufficiently high to produce a defect region 20 having point defects 201. The focused electromagnetic radiation E may scan an area of the semiconductor body 10 to produce a defect region 20 having a desired size.

By means of the electromagnetic radiation E, a density of point defects 201 of at least 1*1013 cm-3 and of at most 1*1019 cm-3 is generated in the defect region 20. An original region 103B adjacent to the defect region 20 is not irradiated by the electromagnetic radiation E. Consequently, a density of point defects 201 in the original region 103B does not change.

Starting from the facet 10A, the defect region 20 extends in the lateral direction X between 1 μm and 1000 μm far into the semiconductor body 10.

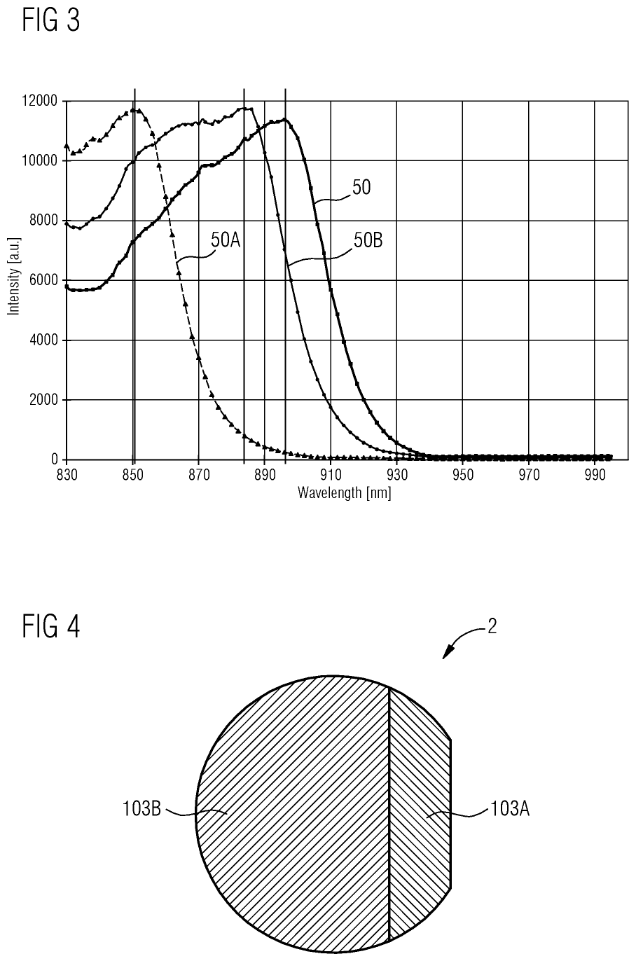

FIG. 2 shows a schematic sectional view of an optoelectronic semiconductor component 1 according to the first embodiment in a further step of a method for its production. In the optoelectronic semiconductor component 1 shown in FIG. 2, the defect region 20 is converted to a conversion region 103A in a previous annealing step. The annealing step is a temperature treatment of the optoelectronic semiconductor component 1 at a temperature between 89° C. and 910° C. for a period of time of at least 30 seconds and at most 20 minutes.

In the annealing step, quantum well intermixing occurs in the quantum well structure in the active layer 103 due to the point defects 201 in the defect region 20, which increases a band gap of the active layer 103 in the conversion region 103A. A band gap in the adjacent original region 103B remains unchanged.

The conversion region 103A extends from an interface of the active layer 103 to the first layer 101 to at most half the thickness D of the active layer 103 into the first layer 101 and from an interface of the active layer 103 to the second layer 102 to at most half the thickness D of the active layer 103 into the second layer 102. At a thickness D of the active layer of 1 μm, the conversion region 103A extends from an interface of the active layer 103 to the first layer 101 to at most 0.5 μm into the first layer 101 and from an interface of the active layer 103 to the second layer 102 to at most 0.5 μm into the second layer 102.

Advantageously, the first layer 101 and the second layer 102 thus retain high radiation transmittance. A density of point defects 201 in the first layer 101 and in the second layer 102 vertically below and above the conversion region 103A is the same as a density of point defects 201 in the first layer 101 and in the second layer 102 vertically below and above the original region 103B. In other words, the density of point defects 201 in the first layer 101 and in the second layer 102 is constant in a direction transverse to the vertical direction Y, respectively.

Furthermore, the conversion region 103A extends from the facet 10A in the lateral direction X between 1 μm and 1000 μm far into the semiconductor body 10. Thus, a recombination probability can be reduced, in particular at the facet 10A, and the facet 10A is advantageously exposed to a lower thermal stress.

FIG. 3 shows several photoluminescence spectra 50, 50A, 50B of an optoelectronic semiconductor component 1 according to the first embodiment at different stages of a process for its production. A first photoluminescence spectrum 50 represents the spectral photoluminescence of an optoelectronic semiconductor component 1 before an annealing step. The maximum of a photoluminescence spectrum provides direct information about a band gap in the material of the optoelectronic semiconductor component 1. A change in a band gap can thus also be observed via a change in the position of the maximum of the photoluminescence spectrum. A global photoluminescence maximum of the first photoluminescence spectrum is located at about 896 nm.

The second photoluminescence spectrum 50A and the third photoluminescence spectrum 50B are from different regions of a optoelectronic semiconductor component 1 after an annealing step at 800° C. for 2 hours. The second photoluminescence spectrum 50A shows the photoluminescence of an original region 103B after the annealing step. A global photoluminescence maximum of the second photoluminescence spectrum is located at about 885 nm.

The third photoluminescence spectrum 50B shows the photoluminescence of a conversion region 103A after the annealing step. A global photoluminescence maximum of the third photoluminescence spectrum is located at about 850 nm. Thus, the photoluminescence maximum of the conversion region 103A has shifted significantly further to shorter wavelengths than the photoluminescence maximum of the original region 103B. Consequently, a significantly stronger quantum well intermixing took place in the conversion region 103A than in the original region 103B.

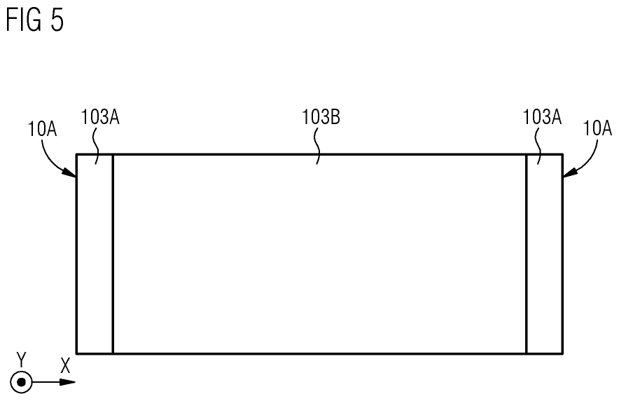

FIG. 4 shows a schematic top view of a wafer composite 2 comprising a plurality of optoelectronic semiconductor components 1 according to the first embodiment. A region of the wafer composite 2 has been irradiated with focused electromagnetic radiation E, thus forming a conversion region 103A, while an adjacent original region 103B has not been irradiated with focused electromagnetic radiation E and is unchanged. Advantageously, the method for producing an optoelectronic semiconductor component 1 is carried out in parallel on a plurality of optoelectronic semiconductor components 1 in a wafer composite 2.

FIG. 5 is a schematic top view of an optoelectronic semiconductor component 1 according to a second embodiment. The second embodiment is substantially the same as the first embodiment, except that a conversion region 103A is formed on both facets 10A of the semiconductor body 10. Advantageously, both facets 10A are thus protected from excessive thermal stress. The conversion region 103A completely covers the facets 10A in each case and, starting from the facet 10A, extends in each case in the lateral direction X between 1 μm and 1000 μm, preferably between 10 μm and 50 μm far into the semiconductor body 10.

The invention is not limited by the description based on the embodiments. Rather, the invention encompasses any new feature as well as any combination of features, which in particular includes any combination of features in the patent claims, even if this feature or combination itself is not explicitly stated in the patent claims or embodiments.

1-17. (canceled)

18. A method for producing an optoelectronic semiconductor component, the method comprising:
A) providing a semiconductor body comprising, sequentially in a vertical direction, a first layer of a first conductivity type, an active layer formed as a quantum well structure provided for emission of electromagnetic radiation, and a second layer of a second conductivity type; and
B) irradiating the semiconductor body with a focused electromagnetic radiation such that a focus region of the electromagnetic radiation lies within the active layer and overlaps with the quantum well structure,
wherein the electromagnetic radiation has an intensity which is sufficiently large in the focus region to cause point defects in the quantum well structure so that a defect region is formed and so that a generation of the point defects is limited to the focus region, and
wherein a density of point defects in the first layer and the second layer is not changed in B).

19. The method for producing the optoelectronic semiconductor component according to claim 18, wherein, in B), the density of point defects in the defect region of at least 1*10¹³ cm⁻³ and of at most 1*10¹⁹ cm⁻³ is generated.

20. The method for producing the optoelectronic semiconductor component according to claim 18, further comprising, in C), performing an annealing such that a conversion region is generated from the defect region, and wherein a band gap in the conversion region is changed with respect to a laterally adjacent original region.

21. The method for producing the optoelectronic semiconductor component according to claim 20, wherein the annealing is carried out at a temperature of at least 800° C. and at most 950° C.

22. The method for producing the optoelectronic semiconductor component according to claim 20, wherein the annealing is carried out over a period of time of at least 30 seconds and at most 20 minutes.

23. The method for producing the optoelectronic semiconductor component according to claim 20, wherein the annealing is carried out at a temperature between 890° C. and 910° C. for a period of 1 to 10 minutes.

24. The method for producing the optoelectronic semiconductor component according to claim 18, wherein irradiating the semiconductor body with the electromagnetic radiation in B) is performed parallel to the vertical direction.

25. The method for producing the optoelectronic semiconductor component according to claim 18, wherein a diameter of the focus region is set to a diameter between 50 nm and 10 μm, inclusive.

26. The method for producing the optoelectronic semiconductor component according to claim 18, wherein a diameter of the focus region is set to a diameter between 100 nm to 200 nm, inclusive.

27. The method for producing the optoelectronic semiconductor component according to claim 18, wherein the electromagnetic radiation has a main wavelength corresponding to a photon energy smaller than a bandgap of a semiconductor material in the first layer and/or in the second layer.

28. The method for producing the optoelectronic semiconductor component according to claim 18, wherein the electromagnetic radiation has a main wavelength corresponding to a photon energy larger than a bandgap of a semiconductor material in the active layer.

29. The method for producing the optoelectronic semiconductor component according to claim 18, wherein the electromagnetic radiation is a coherent radiation.

30. An optoelectronic semiconductor component comprising:
a semiconductor body comprising, in a vertical direction, a first layer of a first conductivity type, an active layer, and a second layer of a second conductivity type,
wherein the active layer is formed as a quantum well structure configured for emission of electromagnetic radiation,
wherein a conversion region is formed in the active layer at least in regions in which a band gap is changed with respect to an original region laterally adjacent thereto, and
wherein a density of point defects in the first layer and the second layer vertically below and above the conversion region is equal to a density of point defects in the first layer and the second layer vertically below and above the original region.

31. The optoelectronic semiconductor component according to claim 30, wherein the conversion region extends from an interface of the active layer to the first layer to at most half of a thickness of the active layer in the first layer, and/or the conversion region extends from an interface of the active layer to the second layer to at most half of the thickness of the active layer in the second layer.

32. The optoelectronic semiconductor component according to claim 30, wherein the conversion region extends in the lateral direction from a facet of the semiconductor body between 1 μm and 1000 μm, inclusive, into the semiconductor body.

33. The optoelectronic semiconductor component according to claim 30, wherein the semiconductor body is based on a III/V compound semiconductor material.

34. The optoelectronic semiconductor component according to claim 33, wherein the semiconductor body is based on a nitride compound semiconductor material, a phosphide compound semiconductor material or an arsenide compound semiconductor material.
